(19) United States
(12) Patent Application Publication
(10) Pub. No.: US 2012/0075943 A1
(43) Pub. Date: Mar. 29, 2012

(54) Method and Apparatus for Memory Repair With Redundant Columns

(75) Inventors: Chia-Jung Chen, Zhubei City (TW); Su-Chueh Lo, Hsinchu (TW); Chin-Hung Chang, Tainan (TW); Chen-Chia Fan, Zhubei City (TW); Kuen-Long Chang, Taipei (TW)

(73) Assignee: Macronix International Co., Ltd., Hsinchu (TW)

(21) Appl. No.: 12/893,235

(22) Filed: Sep. 29, 2010

(51) Int. Cl. G11C 29/04

(52) U.S. Cl. 365/200; 365/230.03

(57) ABSTRACT

A first redundant column is used to repair multiple defects in an array of memory cells. The defects include at least a first defect and a second defect in different main columns of a plurality of main columns in the array. However, all of the multiple defects repaired by the first redundant column are not required to be in different main columns. The array is arranged into a plurality of rows accessed by row addresses and the plurality of main columns accessed by column addresses.

### BACKGROUND

Redundant columns in a memory array improve the manufacturing yield of a memory integrated circuit. Defects in the memory array are repaired by, for example, swapping out a typical column in the memory array which has a defect, and swapping in a redundant column as a replacement for the defective column, by appropriate processing of column addresses.

Unfortunately, defects in a memory array may not be isolated within a same column of the memory array. The technique of swapping in a redundant column as a replacement for the defective column, fails to address defects that occur in different columns of the memory array.

One approach to the problem of defects that occur in different columns of the memory array, is to include more redundant columns. In this fashion, even defects that occur in different columns of the memory array can be addressed, by swapping out each of the defective columns and swapping in a redundant column. Unfortunately, this is an expensive solution because adding additional redundant columns consumes area. Also, in the event that the number of defects in different columns exceeds the number of redundant columns, this technique is exhausted.

### SUMMARY

Memory manufacturing has yield loss from the processing defects. Although the yield is improved by redundant columns to repair the bad columns, the defects from global bit line, local bit line and contact all may use redundant columns to make a repair. Accordingly, there is improved efficiency in a repair that uses less than an entire redundant column.

One aspect is a memory device, comprising an array of memory cells and control circuitry.

The array of memory cells is arranged into a plurality of rows, a plurality of main columns, and a first redundant column. Particular rows in the plurality of rows are identified by row addresses. Particular main columns in the plurality of main columns are identified by column addresses. The first redundant column repairs a first plurality of defects in the array. The first plurality of defects includes a first defect and a second defect in different main columns of the plurality of main columns.

The control circuitry repairs the first plurality of defects in the array with the first redundant column.

In one embodiment, the plurality of rows is divided into a plurality of row blocks, and the first defect and the second defect are in different row blocks of the plurality of row blocks.

In one embodiment, the plurality of rows is divided into a plurality of row blocks, and the first defect and the second defect are in different row blocks of the plurality of row blocks, and a number of the plurality of row blocks corresponds to a number of erase sectors dividing the plurality of rows.

In one embodiment, the plurality of rows is divided into a plurality of row blocks, and the first defect and the second defect are in different row blocks of the plurality of row blocks, and particular rows blocks in the plurality of row blocks are identified by row block addresses. In one embodiment, the memory device further comprises a memory storing information about the first plurality of defects in the array. The memory is accessed by the column addresses and the row block addresses of the first plurality of defects. One embodiment further comprises the memory, a plurality of main sense amplifiers, and a first redundant sense amplifier. The plurality of main sense amplifiers is coupled to the plurality of main columns. The first redundant sense amplifier is coupled to the first redundant column. The memory indicates whether to select the plurality of main sense amplifiers or the first redundant sense amplifier for output from the array.

In one embodiment, the first plurality of defects includes a third defect in a same main column as at least one of the first defect and the second defect. Thus, although the technology uses a redundant column in the array to fix multiple defects in different main columns of the array of memory cells, all of these multiple defects are not required to be in different main columns.

In one embodiment, the first plurality of defects includes a third defect in a different main column as the first defect and the second defect.

In one embodiment, the plurality of columns is divided into a plurality of column blocks having column block addresses. The memory device further comprises a memory storing information about the first plurality of defects in the array. The memory is accessed by the column block addresses and the row block addresses of the first plurality of defects.

One embodiment further comprises a second redundant column that repairs a second plurality of defects in the array. The second plurality of defects includes a third defect and a fourth defect in different main columns of the plurality of main columns.

Another aspect of the technology is a method.

The method repairs, with a first redundant column, a first plurality of defects in an array of memory cells. The first plurality of defects includes a first defect and a second defect in different main columns of a plurality of main columns in the array. The array is arranged into a plurality of rows accessed by row addresses and the plurality of main columns accessed by column addresses.

In one embodiment, the first defect and the second defect are in different row blocks of a plurality of row blocks dividing the plurality of rows. In one embodiment, a number of the plurality of row blocks corresponds to a number of erase sectors dividing the plurality of rows. In one embodiment, particular rows blocks in the plurality of row blocks are identified by row block addresses. One embodiment further includes, accessing a memory by the column addresses and the row block addresses of the first plurality of defects. The memory stores information about the first plurality of defects in the array. In one embodiment, the memory indicates whether to select a plurality of main sense amplifiers coupled to the plurality of main columns or a first redundant sense amplifier coupled to the first redundant column for output from the array.

In one embodiment, the first plurality of defects includes a third defect in a same main column as at least one of the first defect and the second defect. Thus, although the technology uses a redundant column in the array to fix multiple defects in different main columns of the array of memory cells, all of these multiple defects are not required to be in different main columns.

In one embodiment, the first plurality of defects includes a third defect in a different main column as the first defect and the second defect.

One embodiment further includes, accessing a memory by column block addresses and the row block addresses of the first plurality of defects. The memory stores information about the first plurality of defects in the array. The plurality of columns is divided into a plurality of column blocks having the column block addresses.

One embodiment further includes, repairing, with a second redundant column, a second plurality of defects in the array, the second plurality of defects including a third defect and a fourth defect in different main columns of a plurality of main columns in the array.

### BRIEF DESCRIPTION OF THE DRAWINGS

FIG. 1 is a simplified diagram of a memory array with redundant columns that can repair memory defects in different row blocks of the memory array.

FIG. 2 is a simplified overall architecture diagram of a memory circuit with a memory array, such as in FIG. 1, having redundant columns that can repair memory defects in different row blocks of the memory array.

FIG. 3 is a block diagram of the memory that stores data about the defects in the memory array, such as in FIG. 2, divided into multiple row blocks corresponding to the row blocks of the memory array.

FIG. 4 is a block diagram of part of the memory that stores data about the defects corresponding to one row block in the memory array, such as the multiple parts of the memory in FIG. 3.

FIG. 5 is another block diagram of an overall architecture diagram of a memory circuit.

### DETAILED DESCRIPTION

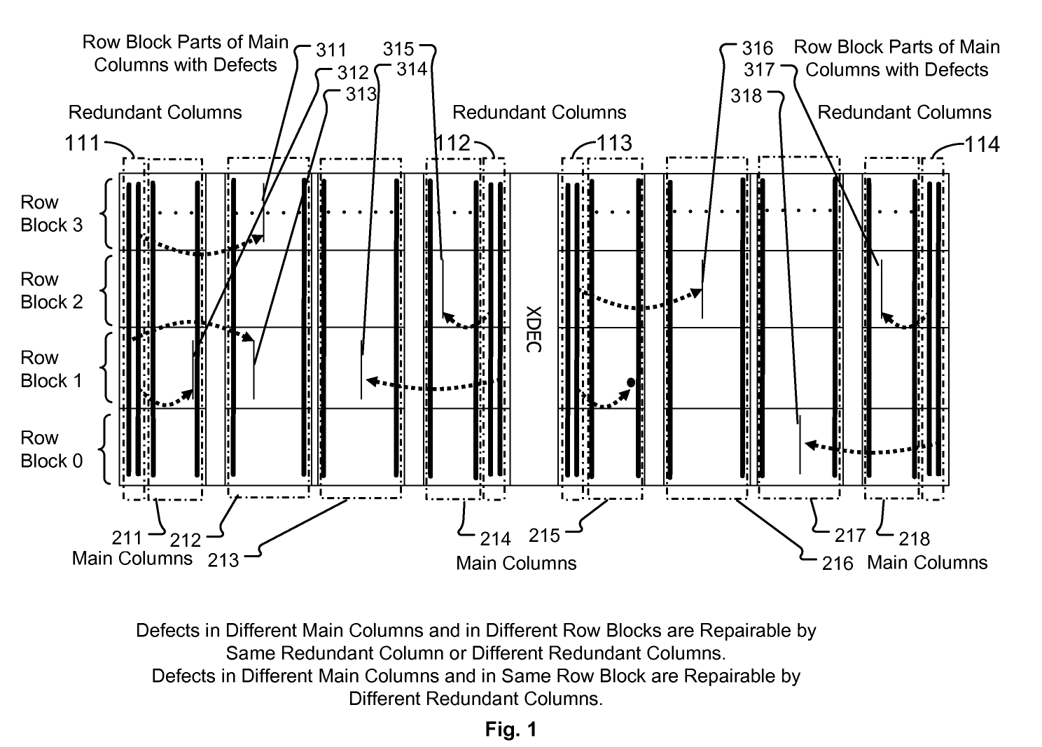

FIG. 1 is a simplified diagram of a memory array with one or more redundant columns that can repair memory defects in different row blocks of the memory array.

The memory array includes main columns 211, 212, 213, 214, 215, 216, 217, and 218, which each extends through all of the row blocks. The main columns on the extreme sides of each half-column block are shown, with ellipsis showing that main columns fill the intervening space of the half-column block. The memory array also includes redundant columns 111, 112, 113, and 114, which each extends through all of the row blocks. The redundant columns repair errors in the main columns.

Embodiments of the technology provide a column repair method and algorithm having a highly efficient repair rate. Each redundant column is divided by N (N=2, 3 . . . to a maximum of the sector number in the Y-axis direction). The repair information is stored in a nonvolatile memory, and during power on downloaded to a memory, such as registers (or fuses). Hence, the repair rate increases by a factor of up to

N times, compared with a relatively inefficient repair rate associated with replacing an entire GBL (global bit line).

In FIG. 1, each column block has its own redundant columns 111/112/113/114. Each redundant column is divided by N in the Y-axis direction. As shown, N=4, but N is practically limited by the sector number in the Y-axis direction.

The same redundant column fixes defects in up to N different main columns, so long as the defects are in different row blocks.

FIG. 1 shows row block parts of main columns with defects 311, 312, 313, 314, 315, 316, 317, and 318, illustrating that the replaceable unit is by row block portion.

Defects in different main columns and in different row blocks are repairable by a same redundant column or different redundant columns. Defects in different main columns and in a same row block are repairable by different redundant columns.

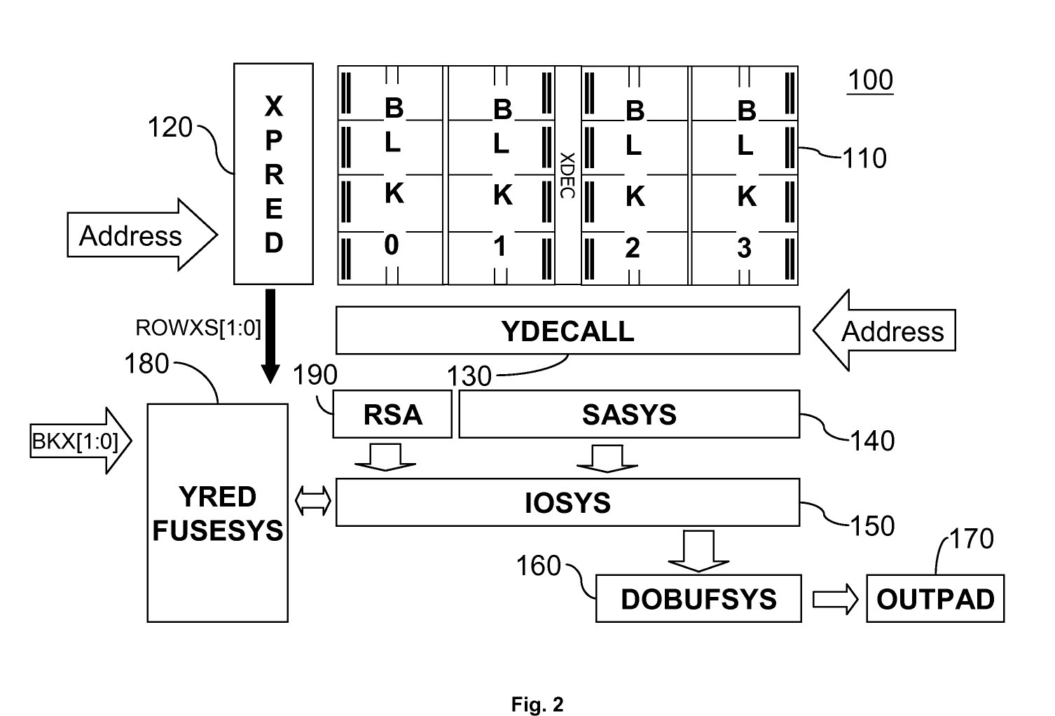

FIG. 2 is a simplified overall architecture diagram of a memory circuit with a memory array, such as in FIG. 1, having redundant columns that can repair memory defects in different row blocks of the memory array.

Each column block—BLK0, BLK1, BLK2, BLK3—has two or more redundant columns. Other embodiments have a different number of column blocks. Various embodiments have a various number of columns per block. Other embodiments have a different number of redundant columns per column block. Redundant columns are divided by N (for example, N=4 in the figure), where N is practically limited by the sector number in the Y-axis direction. Each part of a redundant column—where a redundant column is divided into multiple parts by the row blocks—can repair a defect in its own corresponding row block.

SASYS 140 is a sense amplifier system which has 128 sense amplifiers for one embodiment with an appropriate number of memory array columns. It may have another number of sense amplifiers for a differently sized memory array.

RSA is the redundant sense amplifier system, included in the sense amplifier system SASYS 140, with two sense amplifiers for the redundant columns for the two redundant columns per column block. It may have another number of redundant sense amplifiers in other embodiments with a different number of redundant columns.

IOSYS 150 has a multiplexer to choose the normal sense amplifiers in SASYS 140 coupled to the main memory columns or the redundant sense amplifiers in RSA 190 coupled to the redundant memory columns, according to the repair information from YREDFUSESYS 180. The repair information includes the location of broken memory cells in the memory array 110 and an enable bit.

In one embodiment, there are 9 bits of repair information, including ENABLE,A3,A0,A2,A1,IOBIT[3:0].

During repair analysis, XPRED 120, the x pre-decoder, generates ROWXS[1:0] to select the corresponding row block of array 110. Also, the signals ROWXS[1:0] from XPRED are sent to YREDFUSESYS 180 to perform redundant data analysis. Redundant data are stored in redundant columns, as substitute memory for broken memory cells in the memory array. When a failure has occurred, the corresponding address is latched or otherwise stored in the YREDFUSESYS.

During a read operation, the bad column and redundant column sense in parallel. The sensing result of a bad column is latched in the corresponding sense amplifier, and the result of a redundant column is latched in a redundant sense amplifier. When the addresses match with the repair information of YREDFUSESYS, the YREDFUSESYS generates YREDEN[1:0], IOD1ST[6:0], and IOD2ND[6:0] to be sent to IOSYS 150. Then the sensing data are released from the redundant sense amplifier and the main sense amplifier is inhibited.

With each block having its own redundant columns, there is the advantage of the erase operation for flash memory being executed in a normal sector and the redundant columns at the same time.

The advantage of redundant sense amplifiers, in addition to the main sense amplifiers, is faster reading, because the main array and the redundant columns are sensed in parallel. For example, the page access time is around 25 ns for an example parallel NOR flash with page read. Hence, the pre-sensing for the redundant column is advantageous.

DOBUFSYS 160 is data output buffer system between IOSYS 150 and OUTPAD 170.

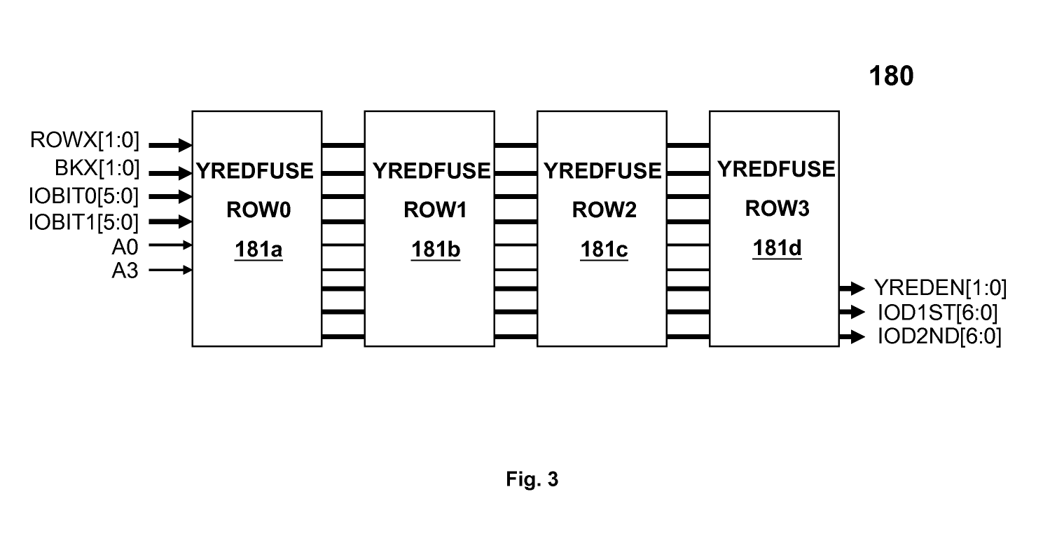

FIG. 3 is a block diagram of the memory that stores data about the defects in the memory array, such as in FIG. 2, divided into multiple row blocks corresponding to the row blocks of the memory array.

The memory of YREDFUSEROW 181 has four blocks for the array cell and each block has two sets of column redundancy. The number of blocks and number of redundant columns have other sizes for other embodiments.

The memory of YREDFUSESYS is divided into four rows—181a, 181b, 181c, and 181d—decoded by ROWX[1:0]. Other embodiments have other sizes decoded by an appropriate number of signals.

The block is decoded by BKX[1:0]. IOBIT0[5:0], IOBIT1[5:0], A0, A3 are information of redundant columns. (A0, A3) is the input address. A0,A1,A2,A3 decide which GBL, as the unit of redundant columns is the global bit line. The information of A0, A1, A2, A3 which indicates a failure location (failure GBL) is stored in YREDFUSESYS during repair analysis.

A1 connects to IOBIT#[4] and A2 connect to IOBIT#[5] , where # is 1 or 2.

IOBIT#[5:0] are for repair analysis to decide the latch data of memory (such as registers or fuses) to indicate the failure location.

There are 16 outputs for this example, using IOBIT[3:0] to decode the output. The information of A0,A3,IOBIT[5:0] is stored in the YREDFUSESYS when a failure is indicated during repair analysis.

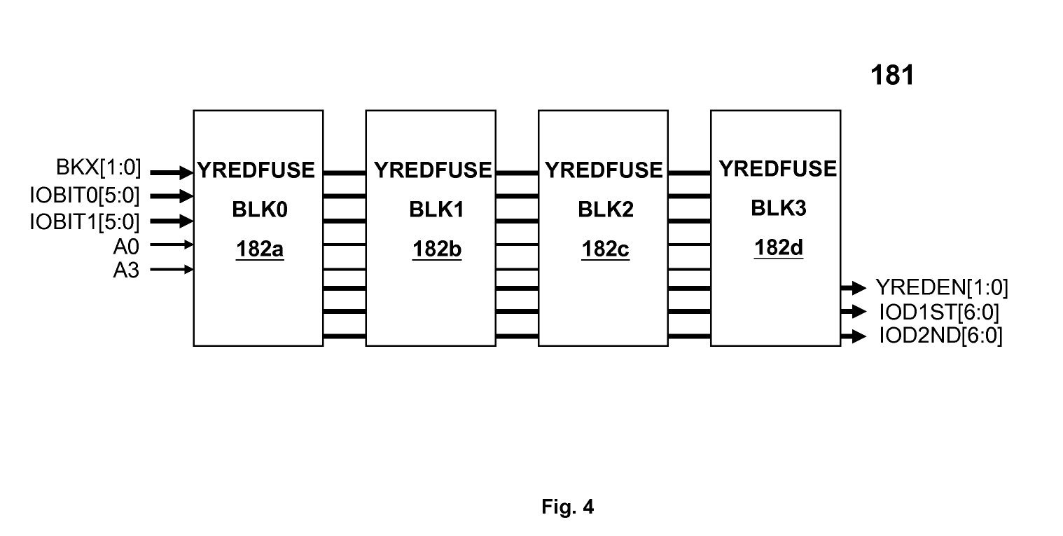

FIG. 4 is a block diagram of part of the memory that stores data about the defects corresponding to one row block in the memory array, such as the multiple parts of the memory in FIG. 3.

Once the address and IO match with the repair information, YREDFUSEBLK 182 generates YREDEN[1:0], IOD1ST[6:0], IOD2ND[6:0] to send to IOSYS to replace error data from a defective part of a main column, with sensed data from a redundant column. IOD1ST[6:0] are the latch data of memory, A0,A2,A1,IOBIT[3:0], stored for the first 1st redundant column. IOD2ND[6:0] is corresponding data for the second redundant column. IOD1ST[6:0] and IOD2ND[6:0] are the result of a match when a user reads the failure location, and are used to indicate the replacement of a particular SA with a particular RSA in IOSYS.

IOBIT0[5:0] consists of the failure location of the first repair column. IOBIT0[3:0] indicates the failure I/O for the example of 16 I/O. IOBIT0[5:4] indicate the failure address A2 and A1. IOBIT1[5:0] consists of the corresponding failure location of the second repair column. Addresses A[3:0] decode the GBLs which is the unit of redundant columns.

There are two redundancy columns for each block. There are two sense amplifiers for the redundant columns. YREDEN[1:0] goes high when the input address A3 matches the failure location stored in the YREDFUSESYS. YREDEN[1:0]and IOD1ST[6:0]/IOD2ND[6:0] decide the replacement of bad sensed data in the SA with replacement sense data in the RSA in IOSYS.

In different embodiments, the row block of array may have other numbers. The maximum may be the number of sectors in the y-axis direction. In different embodiments, the redundant columns of each block may have another quantity.

In different embodiments, the FUSESYS may be, without limitation, be implemented by e-fuses or registers or other nonvolatile memory.

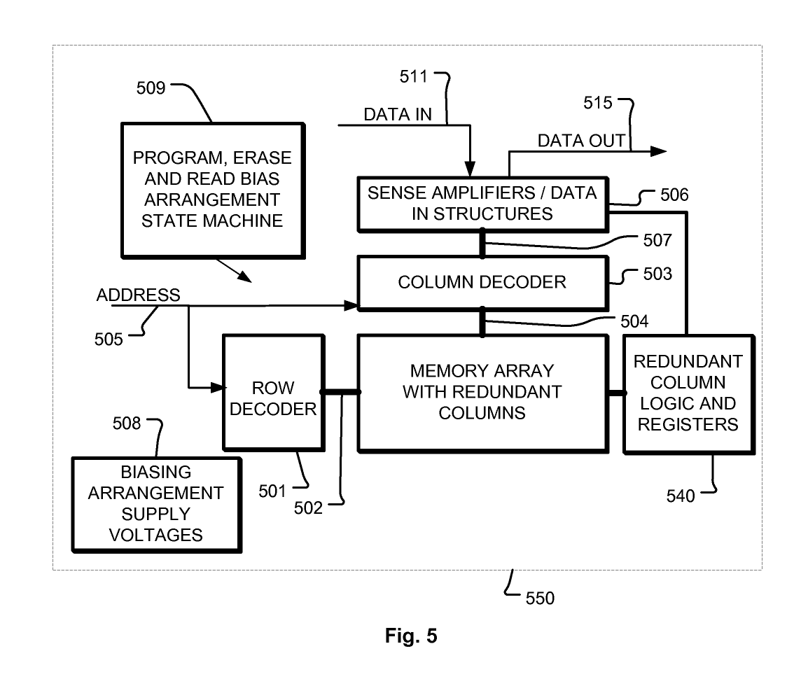

FIG. 5 is another block diagram of an overall architecture diagram of a memory circuit.

FIG. 5 shows an integrated circuit 550 including a memory array 500. A word line and block select decoder 501 is coupled to, and in electrical communication with, a plurality 502 of word lines, and arranged along rows in the memory array 500. A bit line decoder and drivers 503 are coupled to and in electrical communication with a plurality of bit lines 504 arranged along columns in the memory diode array 500 for reading data from, and writing data to, the memory cells in the memory array 500. Addresses are supplied on bus 505 to the word line decoder and drivers 501 and to the bit line decoder 503. Sense amplifiers and data-in structures in block 506, including current sources for the read, program and erase modes, are coupled to the bit line decoder 503 via the bus 507. Data is supplied via the data-in line 511 from input/output ports on the integrated circuit 550, to the data-in structures in block 506. Data is supplied via the data-out line 515 from the sense amplifiers in block 506 to input/output ports on the integrated circuit 550, or to other data destinations internal or external to the integrated circuit 550. A bias arrangement state machine is in circuitry 509, controlling biasing arrangement supply voltages 508. The state machine repairs multiple defects in the array with a redundant column, where defects include at least a first defect and a second defect in different main columns of the array. However, all of the multiple defects repaired by the same redundant column are not required to be in different main columns. Redundant column logic and registers 540 stores repair information about defects in the array 502, and includes control logic to select a main sense amplifier or a redundant sense amplifier in block 506. The data of the registers are downloaded during power on, and programmed to nonvolatile memory after repair analysis.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device, comprising:
an array of memory cells arranged into:
a plurality of rows, wherein particular rows in the plurality of rows are identified by row addresses; and
a plurality of main columns, wherein particular main columns in the plurality of main columns are identified by column addresses;
a first redundant column that repairs a first plurality of defects in the array, the first plurality of defects including a first defect and a second defect in different main columns of the plurality of main columns; and
control circuitry that repairs the first plurality of defects in the array with the first redundant column.

2. The memory device of claim 1, wherein the plurality of rows is divided into a plurality of row blocks, and the first defect and the second defect are in different row blocks of the plurality of row blocks.

3. The memory device of claim 1, wherein the plurality of rows is divided into a plurality of row blocks, and the first defect and the second defect are in different row blocks of the plurality of row blocks, and a number of the plurality of row blocks corresponds to a number of erase sectors dividing the plurality of rows.

4. The memory device of claim 1, wherein the plurality of rows is divided into a plurality of row blocks, and the first defect and the second defect are in different row blocks of the plurality of row blocks, and particular rows blocks in the plurality of row blocks are identified by row block addresses.

5. The memory device of claim 1, wherein the first plurality of defects includes a third defect in a same main column as at least one of the first defect and the second defect.

6. The memory device of claim 1, wherein the first plurality of defects includes a third defect in a different main column as the first defect and the second defect.

7. The memory device of claim 1, wherein the plurality of rows is divided into a plurality of row blocks, and the first defect and the second defect are in different row blocks of the plurality of row blocks, and particular rows blocks in the plurality of row blocks are identified by row block addresses, and the memory device further comprises:
a memory storing information about the first plurality of defects in the array, the memory accessed by the column addresses and the row block addresses of the first plurality of defects.

8. The memory device of claim 1, wherein the plurality of columns is divided into a plurality of column blocks having column block addresses, and the memory device further comprises:
a memory storing information about the first plurality of defects in the array, the memory accessed by the column block addresses and the row block addresses of the first plurality of defects.

9. The memory device of claim 1, wherein the plurality of rows is divided into a plurality of row blocks, and the first defect and the second defect are in different row blocks of the plurality of row blocks, and particular rows blocks in the plurality of row blocks are identified by row block addresses, and the memory device further comprises:
a plurality of main sense amplifiers coupled to the plurality of main columns;
a first redundant sense amplifier coupled to the first redundant column; and
a memory storing data about the first plurality of defects in the array, the memory accessed by the column addresses and the row block addresses of the first plurality of defects, and the memory indicates whether to select the plurality of main sense amplifiers or the first redundant sense amplifier for output from the array.

10. The memory device of claim 1, further comprising:
a second redundant column that repairs a second plurality of defects in the array, the second plurality of defects including a third defect and a fourth defect in different main columns of the plurality of main columns.

11. A method, comprising:
repairing, with a first redundant column, a first plurality of defects in an array of memory cells, the first plurality of defects including a first defect and a second defect in different main columns of a plurality of main columns in the array, wherein the array is arranged into a plurality of rows accessed by row addresses and the plurality of main columns accessed by column addresses.

12. The method of claim 11, wherein the first defect and the second defect are in different row blocks of a plurality of row blocks dividing the plurality of rows.

13. The method of claim 11, wherein the first defect and the second defect are in different row blocks of a plurality of row blocks dividing the plurality of rows, and a number of the plurality of row blocks corresponds to a number of erase sectors dividing the plurality of rows.

14. The method of claim 11, wherein the first defect and the second defect are in different row blocks of a plurality of row blocks dividing the plurality of rows, and particular rows blocks in the plurality of row blocks are identified by row block addresses.

15. The method of claim 11, wherein the first plurality of defects includes a third defect in a same main column as at least one of the first defect and the second defect.

16. The method of claim 11, wherein the first plurality of defects includes a third defect in a different main column as the first defect and the second defect.

17. The method of claim 11, wherein the first defect and the second defect are in different row blocks of a plurality of row blocks dividing the plurality of rows, and particular rows blocks in the plurality of row blocks are identified by row block addresses, and further comprising:
accessing a memory by the column addresses and the row block addresses of the first plurality of defects, the memory storing information about the first plurality of defects in the array.

18. The method of claim 11, further comprising:
accessing a memory by column block addresses and the row block addresses of the first plurality of defects, the memory storing information about the first plurality of defects in the array,
wherein the plurality of columns is divided into a plurality of column blocks having the column block addresses.

19. The method of claim 11, wherein the first defect and the second defect are in different row blocks of a plurality of row blocks dividing the plurality of rows, and particular rows blocks in the plurality of row blocks are identified by row block addresses, and the method further comprises:
accessing a memory by the column addresses and the row block addresses of the first plurality of defects, the memory storing information about the first plurality of defects in the array, the memory indicating whether to select a plurality of main sense amplifiers coupled to the plurality of main columns or a first redundant sense amplifier coupled to the first redundant column for output from the array.

20. The method of claim 11, further comprising:
repairing, with a second redundant column, a second plurality of defects in the array, the second plurality of defects including a third defect and a fourth defect in different main columns of a plurality of main columns in the array.
